(19) United States
(12) Patent Application Publication
(10) Pub. No.: US 2014/0183459 A1
(43) Pub. Date: Jul. 3, 2014

(54) ORGANIC LIGHT EMITTING DEVICE

(71) Applicant: Samsung Display Co., Ltd., (US)

(72) Inventors: Jin-Baek Choi, Yongin-city (KR); Ji-Young Choung, Yongin-city (KR); Joon-Gu Lee, Yongin-city (KR); Hyun-Sung Bang, Yongin-city (KR); Yeon-Hwa Lee, Yongin-city (KR); Won-Jong Lee, Yongin-city (KR)

(73) Assignee: Samsung Display Co., Ltd., Yongin-city (KR)

(21) Appl. No.: 13/850,635

(22) Filed: Mar. 26, 2013

(30) Foreign Application Priority Data
Jan. 2, 2013 (KR) 10-2013-0000274

(51) Int. Cl. H01L 51/50

(52) U.S. Cl. CPC H01L 51/5092
USPC 257/40

(57) ABSTRACT

An organic light emitting device includes: a first electrode disposed on a substrate; a pixel defining layer disposed on the substrate e and patterned so that at least a portion of the first electrode is exposed in a light emitting region; a hole injection layer disposed over the pixel defining layer and the at least a portion of the first electrode exposed in the light emitting region; an organic thin film layer disposed over the hole injection layer; an electron injection layer disposed over the organic thin film layer; and a second electrode disposed on the electron injection layer, the second electrode having an opening configured to expose the electron injection layer in the light emitting region. The organic light emitting device may be implemented in a display device having excellent color-reproduction, when applied to the display device using white light as a light source and the large area display device.

### CROSS-REFERENCE TO RELATED APPLICATIONS

This application claims priority to and the benefit of Korean Patent Application No. 10-2013-0000274, filed on Jan. 2, 2013, in the Korean Intellectual Property Office, the entire content of which is incorporated herein by reference.

### BACKGROUND

1. Field

This present disclosure relates to an organic light emitting device having a non resonant structure.

2. Description of the Related Technology

There are two types of organic light emitting display devices. One type is a passive matrix type, in which an organic light emitting device is connected between a scan line and a data line in a matrix scheme to form a pixel. The other type is a active matrix type in which a thin film transistor acting as a switch controls operations of each pixel. In general, the active-matrix-type organic light emitting display includes a thin film transistor for transferring signals, and a capacitor for maintaining the signals.

The organic light emitting device is composed of an anode electrode, a light emitting layer, and a cathode electrode. The light emitting layer includes a hole transport layer, an organic thin film layer, and an electron transport layer. When voltage is applied between the anode electrode and the cathode electrode, holes injected into the anode electrode and electrons injected into the cathode electrode are coupled to each other in the light emitting layer to generate excitons, and the generated excitons emit light while dropping to a ground state.

The organic light emitting device is classified into a bottom emitting structure type device, in which emitted light moves downward, and a top emitting structure type device, in which emitted light moves upward. The top emitting organic light emitting device has an advantage in which it has a higher aperture ratio relative to the bottom emitting organic light emitting device.

In the organic light emitting device having the top emitting structure, the cathode electrode through which light is transmitted is made of a low work function metal. Although the low work function metal enables high electron mobility to be obtained, reflectivity of the metal may also cause resonance between two electrodes, which may result in brightness change or color shifting according to viewing angles.

### SUMMARY OF CERTAIN INVENTIVE ASPECTS

Disclosed herein are embodiments of an organic light emitting device without brightness change or color shifting according to viewing angles.

The embodiments of the organic light emitting device disclosed herein also having a non resonant structure and a high light emitting efficiency and color reproduction.

According to one aspect of the present invention there is provided an organic light emitting device comprising: a first electrode disposed on a substrate, a pixel defining layer disposed on the substrate and patterned so that at least a portion of the first electrode is exposed in a light emitting region, a hole injection layer disposed over the pixel defining layer and over the at least a portion of the first electrode exposed in the light emitting region, an organic thin film layer disposed over the hole injection layer, an electron injection layer disposed over the organic thin film layer, and a second electrode disposed over the electron injection layer and having an opening configured to expose the electron injection layer in the light emitting region.

The electron injection layer may be made of metal. The metal may be selected from a group composing of alkali metal, alkaline earth metal, and rare earth metal, the electron injection layer may have a thickness configured to prevent resonance with the first electrode, and the second electrode may made of metal having resistivity lower than about 1.5×10-4Ω·cm².

### BRIEF DESCRIPTION OF THE DRAWINGS

The accompanying drawings, together with the specification, illustrate certain embodiments of the present invention, and, together with the description, serve to explain the principles of the present invention.

FIG. 1 is a cross-sectional view illustrating a organic light emitting device according to an embodiment of the present invention.

FIG. 2 is a cross-sectional view illustrating an embodiment of the light emitting layer shown in FIG. 1.

FIG. 3 is a cross-sectional view illustrating another embodiment of the light emitting layer shown in FIG. 1.

FIG. 4 is a flat view illustrating the second electrode shown in FIG. 1.

### DETAILED DESCRIPTION OF CERTAIN INVENTIVE EMBODIMENTS

In the following detailed description, only certain embodiments of the present invention have been shown and described, simply by way of illustration. As those skilled in the art would realize, the described embodiments may be modified in various ways, without departing from the spirit or scope of the present invention. Accordingly, the drawings and description are to be regarded as illustrative in nature and not restrictive. In addition, when an element is referred to as being “on” another element, it can be directly on the other element or be indirectly on the other element with one or more intervening elements interposed therebetween. Also, when an element is referred to as being “connected to” another element, it can be directly connected to the other element or be indirectly connected to the other element with one or more intervening elements interposed therebetween. Hereinafter, like reference numerals generally refer to like elements.

Hereinafter, certain embodiments of the present invention will be described in detail with reference to the accompanying drawings. The embodiments described below, which are to be provided so that those skilled in the art may sufficiently understand the present invention, may be modified in various forms. Therefore the scope of the present invention is not limited to the embodiments described below.

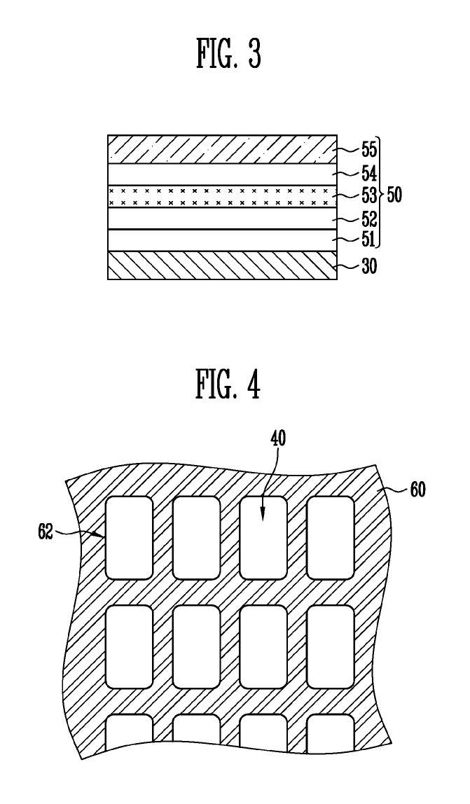

FIGS. 1 and 3 are cross-sectional views illustrating an organic light emitting device according to an embodiment of the present invention.

Referring to FIG. 1, the organic light emitting device includes a first electrode 30, a light emitting layer 50, and a second electrode 60, and may be connected to a thin film transistor.

The thin film transistor includes a gate electrode 12 formed on a substrate 10, a semiconductor layer 16 disposed so as to be insulated from the gate electrode 12 by a gate insulating layer 14, and a source electrode 18 and a drain electrode 20 each connected to a source region and a drain region of the semiconductor layer 16.

Although a bottom gate structure in which the gate electrode 12 is disposed on the bottom of the semiconductor layer 16 is shown in FIG. 1 by way of example, a top gate structure in which the gate electrode 12 is disposed on the top of the semiconductor 16 may be implemented in other embodiments.

The organic light emitting device includes the first electrode 30 connected to the source electrode 18 or the drain electrode 20 of the thin film transistor, the light emitting layer 50 disposed on the first electrode 30 of the light emitting region 40, and the second electrode 60 disposed on the light emitting layer 50.

The first electrode 30 is disposed on the insulating layer 22 formed on the top portion including the thin film transistor, and connected to the source electrode 18 or the drain electrode 20 through a via hole formed in the insulating layer 22. The first electrode 30 may be made of metal such as nickel (Ni), platinum (Pt), gold (Au), sliver (Ag), aluminum (Al), titanium (Ti), molybdenum (Mo), a stack structure thereof, or an alloy metal thereof The first electrode 30 may also be made of a transparent material, such as Iindium Tin Oxide (ITO), Iindium Zinc Oxide (IZO), Iindium Tin Zinc Oxide (ITZO), or the like.

A pixel defining layer 32 is formed on the insulating layer 22 including the first electrode 30, and patterned so that the first electrode 30 in the light emitting region 40 is exposed.

The light emitting layer 50 may be formed on the first electrode 30 of the light emitting region 40 or on the first electrode 30 and a region of the pixel defining layer 32.

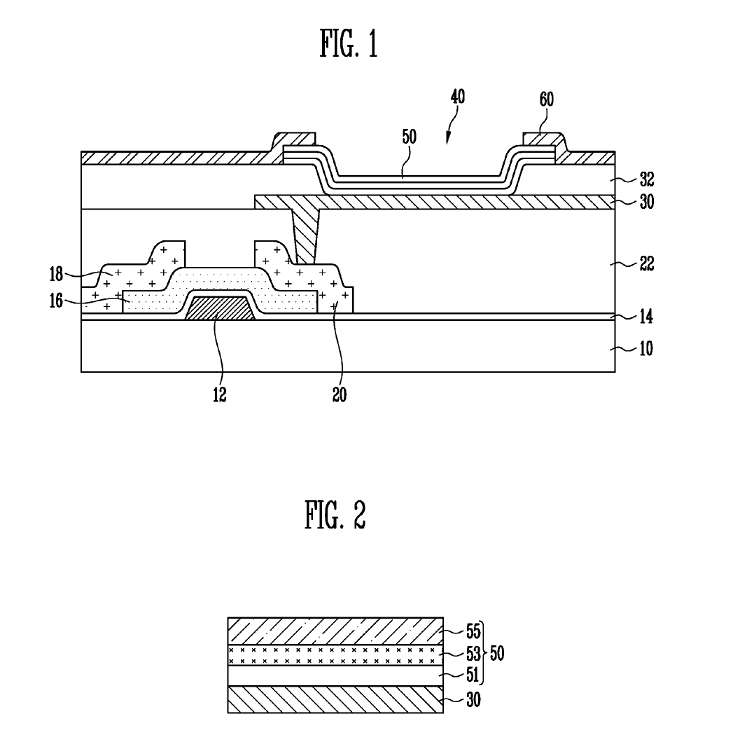

Referring to FIG. 2, the light emitting layer 50 may include a hole injection layer 51 disposed on the first electrode 30, an organic thin film layer 53 disposed on the hole injection layer 51, and an electron injection layer 55 disposed on the organic thin film layer 53. The light emitting layer 50 may further include a hole transport layer 52 disposed between the hole injection layer 51 and the thin film layer 53 and an electron transport layer 54 disposed between the organic thin film layer 53 and the electron injection layer 55, as shown in FIG. 3.

The organic thin film layer 53 is made of a phosphor or fluorescent substance capable of emitting red (R), green (G), or blue (B) light.

The electron injection layer 55 may be made one of alkali metal, alkaline earth metal, or rare earth metal. One metal or one or more alloys selected from a group consisting of Li, Na, K, Cs, Be, Mg, Ca, Sr, Ba, Y, La, Ce, Sm, Gd, Eb, Yb and Al may be used as the above-mentioned metal. In addition, the electron injection layer 55 may have a thickness in which it does not have resonance with the first electrode 30, for example, a thickness from about 10 Å to about 50 Å.

The second electrode 60 is disposed on the electron injection layer 55, and has openings to expose the electron injection layer 55 to the light emitting region 40. The second electrode 60 may be made of a metal such as magnesium (Mg), silver (Ag), aluminum (Al), or a stack structure or alloy thereof, or a transparent material such as ITO, IZO, or ITZO.

Referring to FIG. 4, the second electrode 60 may be disposed in a common electrode on the top portion including a plurality of organic light emitting device, and have openings 62 corresponding to respective light emitting regions of the organic light emitting devices.

The second electrode 60 may be made of a conductive material having low resistivity to allow current to flow smoothly. For example, the second electrode 60 may be made of a metal having resistivity lower than that of ITO (about 1.5×10-4Ω·cm²). In addition, the second electrode 60 may be also formed of a transparent electrode having a transmittance of greater than 90%, or opaque electrode having a transmittance of less than 10%.

The organic light emitting device described above is connected between a power source voltage and a ground voltage. When a signal is input to the gate electrode 12 of the thin film transistor, a predetermined voltage difference between the first electrode 30 and the second electrode 60 is generated. Holes injected through the first electrode 30 and the hole transport layer 51, and electrons injected through the second electrode 60 and the electron transport layer 55 recombine with each other in the organic thin film layer 53 to form excitons, which, in turn, emit light while dropping to a ground state. The emitted light moves outside through the first electrode 30 and the substrate 10, or moves outside through the second electrode 60.

The organic light emitting device has the electron transport layer 55 made of metal, and the second electrode 60 made of material having low resistivity. The formation of openings in the second electrode 60 may make electron injection capacity deteriorate. However, the electron transport layer 55 made of metal makes it possible to minimize voltage drop (IR drop) and thereby maintain electron mobility.

In addition, in the organic light emitting device according to embodiments of the present invention, the formation of openings in the second electrode 60 prevents resonance between the first electrode 30 and the second electrode 60 in the light emitting region 40. The thickness of the electron injection layer 55 set to produce no resonance also prevents resonance in any region other than the light emitting region. The organic light emitting device according to embodiments of the present invention therefore has a non-resonant structure.

When high quality images are desired, a resonant structure having high light extraction efficiency is typically used in order to reproduce natural color. In the resonant structure, the first and second electrodes need to be disposed facing each other. Even though the resonant structure has high light emitting efficiency and easily implements deep-blue, light emitting efficiency may deteriorate at a specific wavelength band due to the resonance effect, or white color may be misrecognized as other colors according to viewing angles. Particularly, the misrecognition presents a serious disadvantage in a display device using white light as a light source and having a color filter.

In order to solve the above-mentioned problems, the second electrode 60 may be made of a transparent material to prevent resonance However, in the process of depositing the transparent material such as ITO, lower layers or an organic thin film layer may be physically or chemically damaged by plasma, or the like.

The organic light emitting device according to embodiments of the present invention has a non resonant structure and enables recognition of white color regardless of viewing angles. The organic light emitting device may implement a display device having excellent color-reproduction, when applied to the display device using white light as a light source and the large area display device.

In addition, a resonant structure may be implemented regardless of the material or reflectivity of the second electrode, thereby making it possible to easily design and manufacture the organic light emitting device.

As set forth above, in the organic light emitting device according to the embodiments of the present invention, the openings formed in the second electrode of the light emitting region prevent resonance from being generated. Therefore problems of the resonant structure, such as, for example, deterioration of light emitting efficiency at a specific wavelength band, misrecognition of white as other colors according to viewing angles, or the like, are solved. In addition, when the organic light emitting device according to embodiments of the present invention is applied to a display device in which a white light is used as a light source or a large area display device, the applied display device has excellent color reproduction.

While the present invention has been described in connection with certain embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An organic light emitting device comprising:
a first electrode disposed on a substrate;
a pixel defining layer disposed on the substrate and patterned so that at least a portion of the first electrode is exposed in a light emitting region;
a hole injection layer disposed over the pixel defining layer and over the at least a portion of the first electrode exposed in the light emitting region;
an organic thin film layer disposed over the hole injection layer;
an electron injection layer disposed over the organic thin film layer; and
a second electrode disposed over the electron injection layer, the second electrode having an opening configured to expose the electron injection layer in the light emitting region.

2. The organic light emitting device according to claim 1, wherein the electron injection layer is made of metal.

3. The organic light emitting device according to claim 2, wherein the metal is selected from a group composing of alkali metal, alkaline earth metal, and rare earth metal.

4. The organic light emitting device according to claim 2, wherein the metal comprises one or more alloys selected from a group consisting of Li, Na, K, Cs, Be, Mg, Ca, Sr, Ba, Y, La, Ce, Sm, Gd, Eb, Yb and Al.

5. The organic light emitting device according to claim 1, wherein the electron injection layer has a thickness configured to prevent resonance with the first electrode.

6. The organic light emitting device according to claim 5, wherein the electron injection layer has a thickness of about 10 Å to about 50 Å.

7. The organic light emitting device according to claim 1, wherein the second electrode is made of a metal having resistivity lower than about 1.5×10-4Ω·cm².

8. The organic light emitting device according to claim 1, wherein the second electrode is made of a metal having a transmittance of less than about 10%.

9. The organic light emitting device according to claim 1, further comprising:
a hole transport layer disposed between the electron injection layer and the organic thin film layer; and
an electron transport layer disposed between the organic thin film layer and the electron injection layer.

10. The organic light emitting device according to claim 1, further comprising a thin film transistor connected to the first electrode.
